(19) United States
(12) Patent Application Publication
(10) Pub. No.: US 2009/0206375 A1
(43) Pub. Date: Aug. 20, 2009

(54) Reduced Leakage Current Field-Effect Transistor Having Asymmetric Doping And Fabrication Method Therefor

(76) Inventors: Samar K. Saha, Milpitas, CA (US); Ashok K. Kapoor, Palo Alto, CA (US)

Correspondence Address: PERKINS COIE LLP, P.O. BOX 1208, SEATTLE, WA, 98111-1208, US

(21) Appl. No.: 12/033,869

(22) Filed: Feb. 19, 2008

(51) Int. Cl. H01L 21/338; H01L 29/812

(52) U.S. Cl. 257/281; 438/174; 257/E21.45; 257/E29.317

(57) ABSTRACT

Reduced leakage current field-effect transistors and fabrication methods. Semiconductor device including substrate of first conductivity type, first well and second well of second conductivity type in substrate, channel of second conductivity type between first well and second well in substrate, and gate region of first conductivity type within channel, wherein gate region is electrically operable to modulate depletion width of channel. First well may be a drain region and the second well may be a source region. Channel includes first link region between gate region and first well or drain region and second link region between the gate region and second well or source region; wherein first link region is of second conductivity type of at least two doping densities. First link region is higher doped in a portion adjacent to drain region than in another portion adjacent to gate region. Method of fabricating a reduced leakage current FET.

### TECHNICAL FIELD

This invention relates generally to semiconductor devices, and, in particular, to field-effect transistors with asymmetric doping profiles for leakage current reduction.

### BACKGROUND

The continued scaling of semiconductor devices (including, but not limited to, transistors) has enabled scaling of operating frequencies to continuously extend Moore's Law. Not only has the scaling of device dimensions increased device performance, it has allowed implementation of complex circuitry in smaller areas, facilitating compactness of portable electronics and other consumer electronics systems.

However, the downwards scaling of the source and drain dimensions in transistors results in decreased amount of mobile carriers yielding low drive current and high channel resistance. Compensation can at least somewhat be achieved by increasing the doping density of the channel region in addition to doping densities in the drain/source regions. However, high doping densities generally render the device susceptible to high-field effects such as, band-to-band (Zener) tunneling effects, which occur at a junction between highly-doped regions (e.g., an n+/p+ junction). In a junction field-effect transistor (JFET), for example, this tunneling generally occurs at the gate/channel junctions.

The tunneling effects contribute to leakage current (e.g., current that flows during an off-state) in JFETs and other types of semiconductor devices. These and other high-field effects potentially lead to increased standby current levels and power dissipation and/or diminished logic operating margins that may significantly impact power consumption and robustness of transistors and digital/analog systems. The battery life of, for example, portable electronics devices can be undesirably shortened. Additional applications may further be deemed unsuitable due to the increased off-state current flow at the transistor level.

### SUMMARY

Reduced leakage current field-effect transistors and fabrication methods are described here. Some embodiments of the present invention are summarized in this section.

In one embodiment, there is provided a semiconductor device, comprising: a substrate of a first conductivity type; a drain region and a source region each of a second conductivity type in the substrate; a channel of the second conductivity type between the drain region and the source region in the substrate; a gate region of the first conductivity type within the channel, the gate region being electrically operable to modulate a depletion width of the channel; and the channel comprising (i) a first link region of the second conductivity type defined between the gate region and the drain region, and (ii) a second link region of the second conductivity type defined between the gate region and the source region; wherein the first link region is more highly doped in a portion adjacent to the drain region than in another portion adjacent to the gate region.

In another embodiment, there is provided a method of fabricating a reduced leakage current field-effect transistor, the method comprising: forming a channel region of a first conductivity type in a substrate; depositing a polysilicon layer on the substrate including on the channel region; patterning the polysilicon layer according to a predetermined location for one or more of, a source region, a drain region, and a gate region; and further doping the channel region between the gate region, which is formed in the channel region, and the drain region with at least two doping levels of the first conductivity type; wherein the source, drain and gate regions are formed in the substrate and spatially separated from each other.

In another embodiment, there is provided a method of differentially doping a field-effect transistor channel formed in a semiconductor substrate and having source, drain, and gate regions which are spatially separated, where the gate region is formed within the channel region, the method comprising: masking at least a portion of the gate region plus the portion of the channel region that extends from an edge of the gate region closest to the drain region to the intermediate position between the edge of the gate region and an edge of the drain region; and diffusing impurities into the un masked portion of the gate and the unmasked portion of the channel between the gate region and the drain region so that the channel region between the gate region and the drain region is doped with at least two different doping levels along the length of the channel between the gate and the drain.

In another embodiment, there are provided semiconductor devices including Field Effect transistors (FETs) and Junction Field Effect transistors (JFETs), made according to the afore described methods.

Other features of the present invention will be apparent from the accompanying drawings and from the detailed description which follows.

### BRIEF DESCRIPTION OF THE DRAWINGS

FIG. 1A illustrates an example of a cross sectional view of an n-type junction field-effect transistor (nJFET) having a link region having uneven doping densities on the source end and the drain end, according to one embodiment.

FIG. 1B illustrates an example of a cross sectional view of a p-type junction field-effect transistor (pJFET) having a link region having uneven doping densities on the source end and the drain end, according to one embodiment.

FIG. 1C illustrates an example of a cross sectional view of complementary junction field-effect transistor having an nJFET and a pJFET, according to one embodiment.
FIG. 2 illustrates a plot comparing on currents (Iₒₙ) and off currents (I_{off}) for symmetrically doped and asymmetrically doped JFETs.

FIG. 3A illustrates an example of cross sectional view of an enhancement mode nJFET depicting channel widths and asymmetric doping density distributions in the on-state, according to one embodiment.

FIG. 3B illustrates an example of cross sectional view of an enhancement mode nJFET depicting channel widths and asymmetric doping density distributions in the off-state, according to one embodiment.

FIG. 4 illustrates an example process flow for fabricating a reduced leakage current JFET, according to one embodiment.

FIGS. 5A-5B illustrates band diagrams of a symmetrically doped nJFET along the depth of the device at the source-side gate edge and the drain-side gate edge, respectively, when the gate-source (V_{gs}) is biased at 0.5V and no drain-source (V_{ds}) bias is applied, according to one embodiment.

FIGS. 6A-6B illustrates band diagrams of a symmetrically doped nJFET along the depth of the device at the source-side gate edge and the drain-side gate edge, respectively, when the gate-source is biased at 0.5V and the drain-source (V_{ds}) is biased, according to one embodiment.

FIGS. 7A-7B illustrates band diagrams of an asymmetrically doped nJFET along the depth of the device at the source-side gate edge and the drain-side gate edge, respectively, when the gate-source (V_{gs}) is biased at 0.5V and no drain-source (V_{ds}) bias is applied, according to one embodiment.

FIGS. 8A-8B illustrates band diagrams of an asymmetrically doped nJFET along the depth of the device at the source-side gate edge and the drain-side gate edge, respectively, when the gate-source is biased at 0.5V and the drain-source (V_{ds}) is biased, according to one embodiment.

### DETAILED DESCRIPTION

The following description and drawings are illustrative and are not to be construed as limiting. Numerous specific details are described to provide a thorough understanding of the invention and embodiments of the invention. However, in certain instances, well-known or conventional details are not described in order to avoid obscuring the description.

Reference in this specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment, nor are separate or alternative embodiments mutually exclusive of other embodiments. Moreover, various features are described which may be exhibited by some embodiments and not by others. Similarly, various requirements are described which may be requirements for some embodiments but not other embodiments.

The terms used in this specification generally have their ordinary meanings in the art, within the context of the invention, and in the specific context where each term is used. Certain terms that are used to describe the invention and examples and embodiments of the invention are discussed below, or elsewhere in the specification, to provide additional guidance to the practitioner regarding the description of the invention. For convenience, certain terms may be highlighted, for example using italics and/or quotation marks. The use of highlighting has no influence on the scope and meaning of a term; the scope and meaning of a term is the same, in the same context, whether or not it is highlighted. It will be appreciated that same thing can be said in more than one way.

Consequently, alternative language and synonyms may be used for any one or more of the terms discussed herein, and no special significance should be placed upon whether or not a term is elaborated or discussed herein. Synonyms for certain terms are provided. A recital of one or more synonyms does not exclude the use of other synonyms. The use of examples anywhere in this specification including examples of any terms discussed herein is illustrative only, and is not intended to further limit the scope and meaning of the written description or of any example term. Likewise, the written description and disclosure is not limited to various embodiments given in this specification.

Without intent to further limit the scope of the invention, examples of instruments, apparatus, methods and their related results according to the embodiments of the present invention are given below. Note that titles or subtitles may be used in the examples for convenience of a reader, which in no way should limit the scope of the invention. Unless otherwise defined, all technical and scientific terms used herein have the same meaning as commonly understood by one of ordinary skill in the art to which this invention and art pertains. In the case of conflict, the present document, including definitions will control.

The terminology used in the description presented below is intended to be interpreted in its broadest reasonable manner, even though it is being used in conjunction with a detailed description of certain specific examples of the invention. Certain terms may even be emphasized below; however, any terminology intended to be interpreted in any restricted manner will be overtly and specifically defined as such in this Detailed Description section.

Embodiments of the present invention include reduced leakage current field-effect transistors and fabrication methods thereof.

Although embodiments of the present invention are described with example reference to junction field effect transistors (JFET), the application of the novel aspect of the invention is not limited as such. Applications of the principles of leakage current reduction disclosed herein to other types of devices of additional or same materials systems (e.g., Si, Ge, GaAs, other III-V systems, etc.) are contemplated and are considered to be within the scope of this invention, including but not limited to, metal-semiconductor field effect transistors (MESFETs), Ge/Si FETs, and/or any other semiconductor device whereby charge transport is performed by majority carriers.

The terms, chip, integrated circuit, monolithic device, semiconductor device or component, microelectronic device or component, and similar expressions, are often used interchangeably in this field. The present invention is applicable to all the above as they are generally understood in the field.

The term “gate” is context sensitive and can be used in two ways when describing integrated circuits. While the term gate may refer to a circuit for realizing an arbitrary logical function when used in the context of a logic gate, as used herein, gate refers to the gate electrode of a three terminal field effect transistor (FET). In some instances, although a FET can be viewed as a four terminal device when the semiconductor body is considered, for the purpose of describing illustrative embodiments of the present invention, the FET will be described using the traditional gate-drain-source, three terminal model.

Polycrystalline silicon is a nonporous form of silicon made up of randomly oriented crystallites or domains. Polycrystalline silicon is often formed by chemical vapor deposition from a silicon source gas or other methods and has a structure that contains large-angle grain boundaries, twin boundaries, or both. Polycrystalline silicon is often referred to in this field as polysilicon, or sometimes more simply as poly.

Source/drain terminals refer to the terminals of a FET, between which conduction occurs under the influence of an electric field. Current conduction between the source/drain terminals are modulated by the gate bias applied to the gate terminal. For example, in an enhancement-mode or depletion-mode JFET device.

Source/drain terminals are typically formed in a semiconductor substrate and have a conductivity type (i.e., p-type or n-type) that is of the same conductivity type of the channel of a JFET. Sometimes, source/drain terminals are referred to as junctions.

Generally, the source and drain terminals are fabricated such that they are geometrically symmetrical. Source/drain terminals may be additionally coupled to link regions sometimes referred to as extensions, which are generally shallower than other portions of the source/drain terminals. The link regions typically extend along the channel region of a FET, from the source/drain regions. Designers often designate a particular source/drain terminal to be a “source” or a “drain” on the basis of the voltage to be applied to that terminal when the FET is operated in a circuit.

The terms ‘asymmetric link regions’ and ‘asymmetric doping’ are used interchangeably to describe the asymmetricity in the spatial distribution of doping densities on the two sides of the gate (e.g., the drain side and the source side).

Contrastingly, the term ‘symmetric link regions’ and ‘symmetric doping’ are used interchangeably to describe the asymmetricity in the spatial distribution of doping densities on the two sides of the gate (e.g., the drain side and the source side).

The term depth, as used herein, means substantially perpendicular to the surface of a substrate.

The term length, as used herein, means substantially parallel to the surface of a substrate in the direction along the “source” and “drain” terminals of a FET.

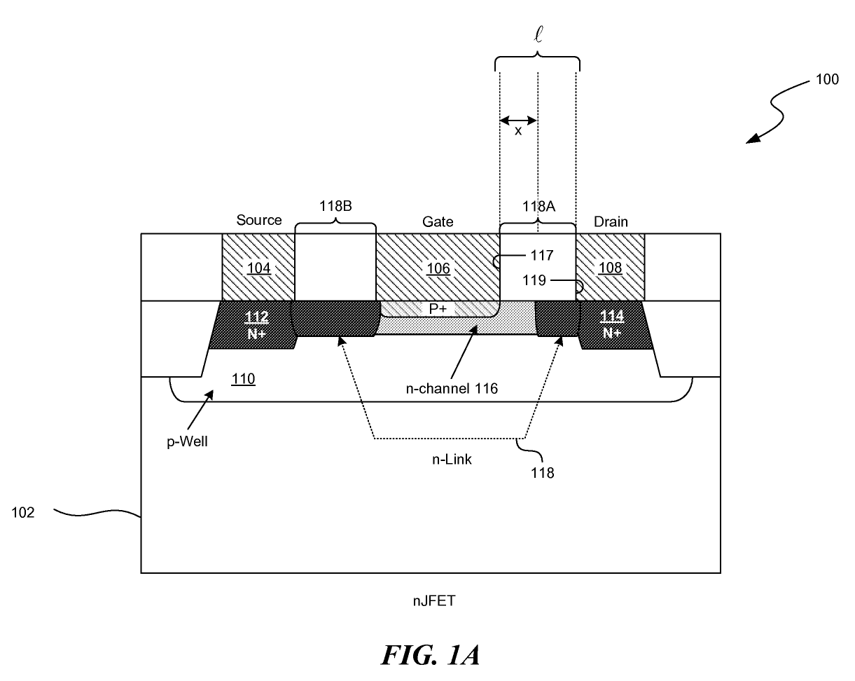

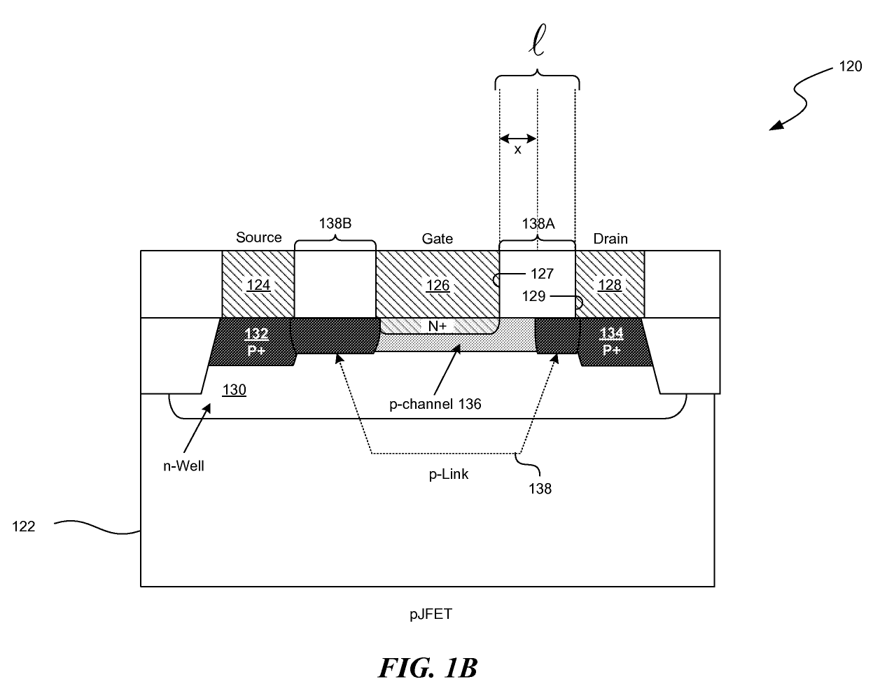

FIG. 1A illustrates an example of a cross sectional view 100 of an n-type junction field-effect transistor (nJFET) 102 having a link region 118 having uneven doping densities on the source end 112 and the drain end 114, according to one embodiment.

The nJFET 102 may be fabricated from any known and/or convenient methods. The nJFET 102 includes heavily doped polysilicon contacts including, a source terminal 104, a gate terminal 106, and a drain terminal 108. The nJFET 102 further includes a p-type doped region 110 in which a well region 112 (e.g., source region 112) and another well region 114 (e.g., the drain region 114) are formed. The p-type doped region 110 is sometimes referred to as a p-well. Additionally, the channel region 116 (e.g., n-channel) may be formed along the source region 112 and the drain region 114 in the p-well 110.

The nJFET 102 further includes link regions 118 (e.g., n-link region) extending from the source region 112 and the drain region 114 towards the gate region, respectively. The link regions 118 of the nJFET 102 are generally doped with n-type impurities so as to provide additional charge carries during on-state of the nJFET 102. The link regions 118 provide carriers in addition to that supplied via the source region 112, drain region 114, and the channel region 116.

In one embodiment, the link region 118 comprises a first link region 118A between the drain /gate and a second link region 118B between the source/gate. The doping densities of the first link region 118A and second link region 118B are distributed asymmetrically about the gate region as illustrated by the varying shades along the channel region 116. Although two shades are illustrated, more than one doping densities along the channel as provided by the link region 118 are contemplated and is considered to be within the novel art of this invention.

For example, the doping density of second link region 118B is uniform along the channel length between the source 112 and the gate whereas doping density of the first link region 118A is unevenly distributed between the drain region 114 and the gate region. In general, to achieve reduced leakage current in a field-effect transistor, the doping density of the first link region 118A increases in portions closer to the drain region 114. The higher doped region of the first link region 118A is offset from the drain-side gate edge to prevent junctions of highly doped regions from forming between the gate and channel junction due to susceptibility to high-field effects such as band-to-band tunneling.

Although an abrupt doping profile is illustrated in the first link region 118A, in accordance with non-limiting embodiments, additional doping profiles (e.g., graded-doping profile) that increase the doping density of the first link region 118A approaching the drain region 114 are contemplated and are considered within the novel aspects and features of the embodiments. In one embodiment, the doping profile is graded both laterally and vertically; however, since the junction is very shallow, the grading can be considered abrupt.

With further reference to FIG. 1A, in one embodiment, the first link region 118A includes two regions with different doping densities of the same conductivity type (e.g., majority carrier—n-type impurities). For example, the first link region 118A can include a lower doped region extending along the channel from the drain-side gate edge 117 to a midway or other intermediate position between the drain-side gate edge 117 and a drain edge (e.g., gate-side drain edge) 119 and a higher doped region extending along the channel from the midway or other intermediate position (e.g., offset ‘x’), to the to the drain edge (e.g., gate-side drain edge) 119. The lower doped region may be of substantially similar doping levels or densities as the channel doping levels or densities.

In general, the offset of a distance ‘x’ of the higher doped region can be any fraction of the distance ‘1’ between the gate edge 117 and drain edge 119. In one embodiment, the higher doped region is offset approximately midway from the center (e.g., x˜l/2) of the gate edge 117 and the drain edge 119. In some embodiments, the offset ‘x’ of the higher doped region can be anywhere approximately between a lower end of 15 nanometers (nm.) to a higher end of l/2. In still other non-limiting embodiments, the higher end of the offset ‘x’ may be l/32, l/16, l/18, l/4, l/2, 3l/4, 7l/8, 9l/8, 5l/4, 3l/2, 7l/4, or any other intermediate value. The 15 nm. offset corresponds to the band banding (e.g., depletion width) between the gate and channel regions of the preferred doping densities.

In general, the minimum length of the offset ‘x’ is governed by the band banding between the gate and channel junction. Accordingly, in one embodiment, the minimum length offset ‘x’ is substantially the length of the band banding at the gate/channel junction for any gate doping density and any channel doping density. For example, there may be situations under which the gate and channel regions are higher doped thus shortening the depletion width to the range between substantially 4 nm and 15 nm, and in particular non-limiting embodiments the depletion width may fall within the ranges of approximately 4-8 nm, 8-11 nm, or 11-15 nm, or some other width. Contrastingly, the gate and channel regions may be lower doped thus increasing the band bending length to the range between substantially 15 nm and 30 nm, and in particular non-limiting embodiments the band bending length may fall within the ranges or approximately 15-20 nm, 20-25 nm, or 25 nm-30 nm. These depletion width and band bending lengths are exemplary and the particular ranges are provided by way of example and not by way of limitation.

The gate edge 117 referred to above is the edge that is proximal to the drain region (e.g., drain well 114) and the drain edge 119 (e.g., edge of drain well) is the edge that is proximal to the gate region 106. The second link region 118B generally has a doping density that is substantially similar to that of the higher doped region of the first link region 118A.

In a preferred embodiment, the doping density of the higher doped region in the first link region 118A is approximately an order of magnitude greater than that of the lower doped portion in the first link region 118A. In practice, the higher doping density can be anywhere between approximately twice (2×) the lower doping density and up to the solubility limit of the particular material (e.g., typically 2e²⁰/cm³) but usually between 2-50× of the lower doping density.

Multiple ranges of elevated doping densities are possible, including but way of example but not limitation ranges between 2 times (e.g. 2×) and 50 times (e.g., 50×) or more, and may for example be in the ranges of 2-5×, 5-10×, 10-15×, 20-25×, 25-30×, 30-35×, 35-40×, 40-45×, or 45-50×. In some instances the higher doping density may be between 50×-200× of the lower doping density. In particular the higher doping density can be 50-75× or 75×-100× of the lower doping density. For example, the doping density of the lower doped region 116 (e.g., channel doping) is typically approximately 1e¹⁸-1e⁹/cm³ and the doping density of the higher doped region 118B and portions of 118A is typically approximately 1e¹⁹-2e²⁰/cm³.

Methods for operating a JFET (nJFET and/or pJFET) and the related principles of operations (e.g., in the enhancement mode and the depletion mode) are well known to those skilled in the art and are not further described here. In one embodiment, the nJFET operates in the enhancement mode, or otherwise referred to as the normally-off mode. The inventive semiconductor devices and structures operating in these modes have enhanced operating characteristics and performance over conventional devices and structures, including by way of example, but not limitation, reduced off-state leakage current and other implications thereof.

FIG. 1B illustrates an example of a cross sectional view 120 of a p-type junction field-effect transistor (pJFET) 122 having a link region 138 having uneven doping densities on the source end 132 and the drain end 134, according to one embodiment.

The pJFET 122 includes heavily doped polysilicon contacts including, a source terminal 124, a gate terminal 126, and a drain terminal 128. The pJFET 122 further includes an n-type doped region 130 in which the source region 132 and the drain region 134 are formed. The n-type doped region 130 is also often referred to as an n-well. Additionally, the channel region 136 (e.g., p-channel) may be formed along the well (e.g., source region 132) and the well (e.g., drain region 134) in the n-well 130.

The pJFET 122 further includes link regions 138 (e.g., p-link region) extending from the source region 132 and the drain region 134 towards the gate region, respectively. The link regions 138 of the pJFET 122 are generally doped with p-type impurities so as to provide additional charge carries during on-state of the pJFET 122. The link regions 138 provide carriers in addition to that supplied via the source region 132, drain region 134, and the channel region 136.

In one embodiment, the link region 138 comprises a first link region 138B between the source /gate and a second link region 138A between the drain/gate. The doping densities of the first link region 138A and second link region 138B are distributed asymmetrically about the gate region as illustrated by the varying shades along the channel region 136. Although two shades are illustrated, more than one doping densities along the channel as provided by the link region 138 are contemplated and is considered to be within the novel art of this invention.

For example, the doping density of second link region 138B is uniform along the channel length between the source 132 and the gate where as doping density of the first link region 138A is unevenly distributed between the drain region 134 and the gate region. In general, the doping density of the first link region 138A increases or is higher closer to the drain region 134. The higher doped region of the first link region 138A is offset from the gate edge to prevent junctions of highly doped regions from forming between the gate and channel junction due to susceptibility to high-field effects such as band-to-band tunneling.

Although an abrupt or nearly abrupt doping profile is illustrated in the first link region 138A, in accordance with non-limiting embodiments, additional types of doping profiles (e.g., graded-doping profile) that increase the doping density of the first link region 138A approaching the drain region 134 are contemplated and are considered within the novel art of the invention. In one embodiment, the doping profile is graded both laterally and vertically. However, sine the junction is very shallow, the grading can be considered abrupt.

In one embodiment, the first link region 138A includes two regions with different doping densities of the same conductivity type (for example, majority carrier, p-type impurities). For example, the first link region 138A can include a region with a lower doping density extending along the channel from the gate edge 127 to a midway or other intermediate position between the gate edge 127 and a drain edge 129 (e.g., edge of drain well) and a higher doped region extending along the channel from the midway or other intermediate position, to the drain edge 129 (e.g., edge of drain well). The lower doped region of the first link region 138A may be of similar doping levels to the doping levels of the channel doping. In one embodiment, the low doping region is substantially the same as the channel doping concentration.

In general, the offset distance ‘x’ of the higher doped region can be any fraction of the distance ‘l’ between the gate edge and drain edge. In one embodiment, the higher doped region is offset approximately midway from the center of the gate edge and the drain edge (e.g., x˜l/2). In some embodiments, the offset ‘x’ of the higher doped region can be anywhere between approximately between 15 nanometers (nm) to l/2. In still other non-limiting embodiments, the offset may be l/32, l/16, l/8, l/4, l/2, 3l/4, 7l/8, or any other intermediate value.

The 15 nm offset corresponds substantially to the band banding (e.g., depletion width) between the gate and channel regions of the preferred doping densities according to one non-limiting embodiment.

In general, the minimum length of the offset ‘x’ is governed by the band banding between the gate and channel junction. Accordingly, in one embodiment, the minimum length offset ‘x’ is substantially the length of the band banding at the gate/channel junction for any gate doping density and any channel doping density. For example, there may be situations under which the gate and channel regions are higher doped thus shortening the depletion width to approximately 4-8 nm, 8-11 nm, or 11-15 nm. Contrastingly, the gate and channel regions may be lower doped thus increasing the band bending length to approximately 15-20 nm, 20-25 nm, or 25 nm to 30 nm.

The gate edge 127 referred to above is the edge of the gate that is proximal to the drain region (e.g., drain well) 134 and the drain edge 129 (e.g., edge of drain well 134) is the edge that is proximal to the gate region 126. The second link region 138B generally has a doping density that is substantially similar to that of the higher doped region of the first link region 138A. In one embodiment, the low doping region is substantially the same as the channel doping concentration. In one embodiment, both link regions may have the same or substantially the same doping concentrations as they may be formed using the same implant procedure. In one embodiment, the doping concentrations or densities may be different, and for example the drain-side link region doping may be higher and the same or substantially the same as the deep source-drain regions. In another embodiment, the drain-side link region doping is higher than the deep-source drain regions.

In one embodiment, the doping density of the higher doped region in the first link region 138A is approximately an order of magnitude greater than that of the lower doped portion in the first link region 138A. The higher doping density can be anywhere between 2× of the lower doping density up to the solubility limit of the particular material (e.g., typically 2e²⁰/cm³) but usually between 2-50× of the lower doping density.

Multiple ranges of elevated doping densities are possible, including but way of example but not limitation higher doping densities in the range from 2× to 50× relative to the lower doping densities, such as for example doping densities that are 2-5×, 5-10×, 10-15×, 20-25×, 25-30×, 30-35×, 35-40×, 40-45×, or 45-50×. In some instances the higher doping density may be between 50×-200× of the lower doping density. In particular the higher doping density can be 50-75× or 75×-100× of the lower doping density. For example, the doping density of the lower doped region (e.g., channel doping 116) is typically approximately 1e¹⁸-1e¹⁹/cm³ and the doping density of the higher doped region 138B and portions of 138A is typically approximately 1e¹⁹-2e²⁰/cm³.

In one embodiment, the pJFET operates in the enhancement mode, or otherwise referred to as the normally-off mode.

FIG. 1C illustrates an example of a cross sectional view of complementary junction field-effect transistor 142 having an nJFET 152 and a pJFET 162, according to one embodiment.

The nJFET 152 and the pJFET 162 may be fabricated with known material (e.g., Si, Ge, Ge/Si, CMOS grade silicon, GaAs, or other III-V systems, etc.). The nJFET 152 includes an unevenly doped link region 158 (e.g., n-link) and is described with further reference to the description of FIG. 1A. The pJFET 162 includes an unevenly or asymmetrically doped link region 168 (e.g., p-link) and is described with further reference to the description of FIG. 1B. The nJFET 152 and pJFET 162 are laterally spaced apart from one another in the substrate (e.g., p-substrate) and are electrically isolated from one another by the shallow trench isolation structure 170.

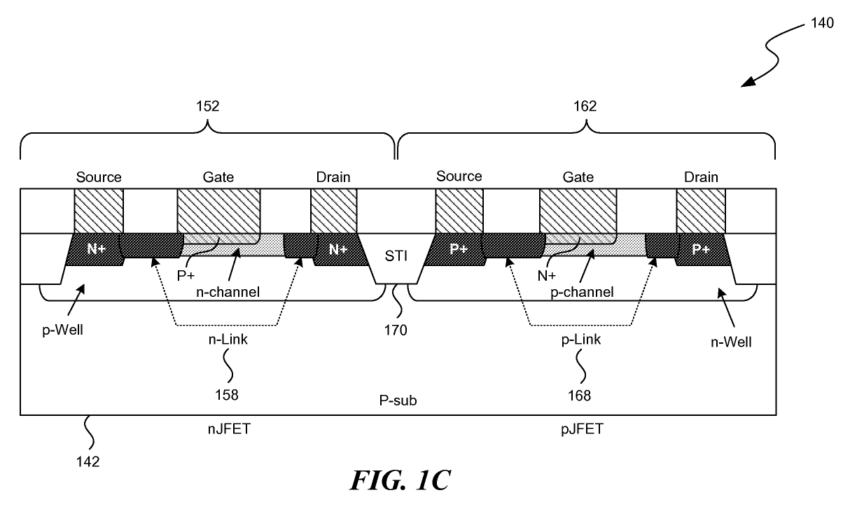

FIG. 2 illustrates a graphical plot 200 comparing on currents (Iₒₙ) and off currents (I_{off}) for symmetrically doped and asymmetrically doped JFET source and drains (S/D).

Data obtained for the symmetrically doped JFET is obtained from a channel/source/drain doping density of 5e¹⁹/cm³ and a gate doping density of 1e²⁰/cm³. The current variation is obtained by varying the channel doping density. In the symmetric device, the channel concentration is between 1.7e¹⁹-2.1e¹⁹/cm³. The peak link doping density is approximately 4e¹⁹/cm³. The asymmetrically doped JFET used in this experiment and simulations has a gate/drain side link region 118 (See for example FIG.1A) having channel concentration between 1.65e¹⁹-1.9e¹⁹/cm³ and a high doping density of 1e²⁰/cm³. The low doping density region spans approximately one-half of the length between the gate edge 117 and the drain edge 119 and is located proximal to the gate 106, as shown in the example of FIG. 1A. The high doping density region spans approximately half of the length between the gate edge 117 and the drain edge 119 and is located proximal to the drain, as shown in the example of FIG. 1A. The gate doping density for the asymmetric device is also 1e²⁰/cm³. The gate bias (V_{gs}) is 0.5V in both cases.

Curve 202 illustrates the ratio of Iₒₙ/I_{off} for the asymmetric device. Curve 204 illustrates Iₒₙ/I_{off} for the symmetric device. Iₒₙ represents the saturated drain current. As illustrated, the asymmetric JFET has a higher Iₒₙ/I_{off} ratio for a wide range of operating conditions (e.g., for on-currents between 40-140 μA/μm). Curve 206 illustrates the off-state leakage current level (I_{off}) for the symmetric JFET vs. the on current (Iₒₙ). Curve 208 illustrates the off-state leakage current level (I_{off}) for the asymmetric JFET vs. the on current (Iₒₙ). As can be seen, for a wide range of operating conditions (e.g., drain current between 40-140 μA/μm), the symmetric device typically has a higher off-state leakage current as the asymmetric device has a lower off-state leakage current (as illustrated by curve 208) for all on-currents illustrated in the plot.

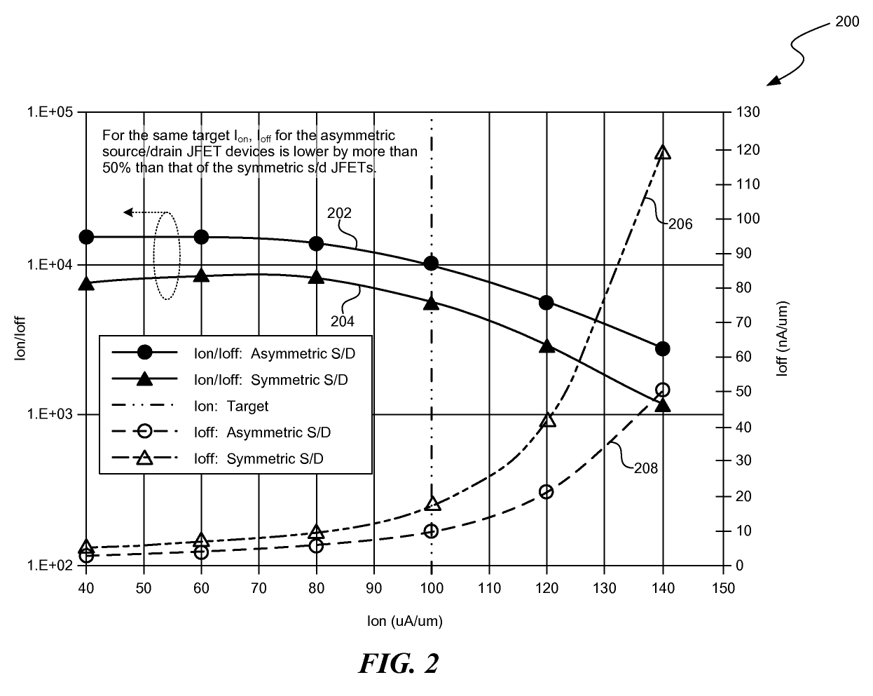

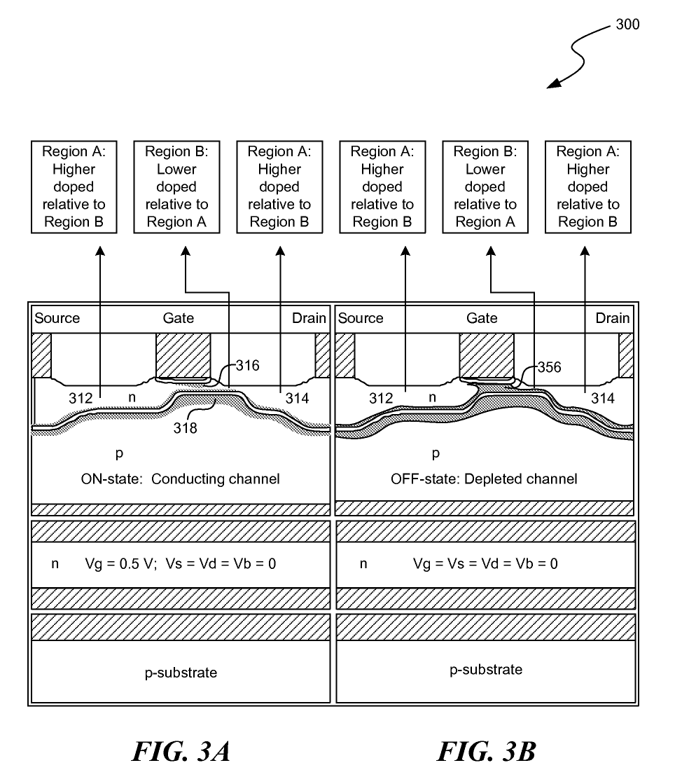

FIG. 3A illustrates an example of cross sectional view of an enhancement mode nJFET 300 depicting channel widths and asymmetric doping density distributions in the on-state, according to one embodiment.

FIG. 3B illustrates an example of cross sectional view of an enhancement mode nJFET 300 depicting channel widths and asymmetric doping density distributions in the off-state, according to one embodiment.

The nJFET 300 for which channel widths are plotted has asymmetric link regions 312 and 314 about the gate, as is further implicated by the asymmetric distributions of the depletion depth 318 and 356 about the source side of the gate and the drain side of the gate. In accordance with one embodiment of the present invention, the first link region 314 is more highly doped closer to the drain end than near the gate end.

In the on-state of the nJFET as illustrated in the example of FIG. 3A, the channel is open between the gate depletion 316 and the junction depletion 318 due to the applied gate bias. The gate bias in the on-state decreases the reverse bias at the gate-channel junction thus shrinking the gate depletion 316 and junction depletion 318 as compared to the zero bias condition (off-state) as illustrated in the example of FIG. 3B. The open channel allows carriers to flow between the source and drain. For an enhancement mode JFET, the channel is closed due to a fully depleted channel 356 under a zero gate bias as shown in the example of FIG. 3B.

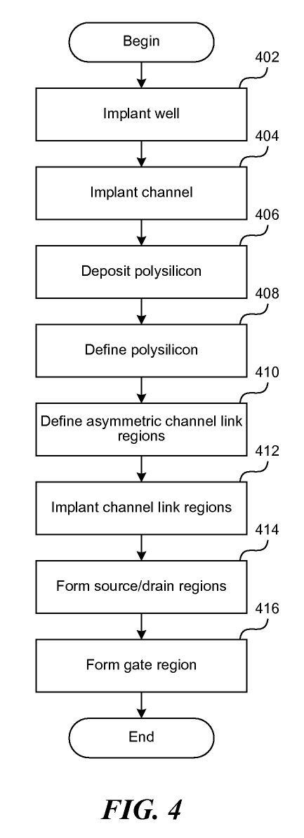

FIG. 4 illustrates an example process flow for fabricating a JFET having a higher doped channel region adjacent to the drain, according to one embodiment.

In process 402, a well is implanted in a substrate. The well implant can be formed according to any known and/or convenient manner. Generally, an n-well is formed for a pJFET and a p-well is formed for an n-JFET.

In process 404, the channel region is implanted. The channel region may be formed according to any known and/or convenient manner, for example, by dopant diffusion. For an nJFET or pJFET, the channel depth is generally approximately 45-55 nm although other depths may be implemented, without deviating from the novel aspects and features of the embodiments.

For an n-JFET, n-type dopants are used for channel formation. For a p-JFET, p-type dopants are used for channel formation. By way of example but not limitation, in a silicon based device, materials with five valence electrons such as phosphorus and/or arsenic can be used to for n-type doping and materials with three valence electrons such as boron and/or gallium can be used for p-type doping.

In process 406, polysilicon is deposited on the device. The polysilicon may be doped using any suitable technique, such as diffusion, ion implantation, or in-situ doping. For example, in an nJFET, the source-drain polysilicon may be selectively doped using n-type impurities. When a pJFET is constructed the source-drain polysilicon may be selectively doped using p-type impurities.

In process 408, the polysilicon layer is defined. The polysilicon may be defined via any selective etching process (e.g., plasma etch, chemical etch, dry etch, wet etch, etc.) to form the source, gate, and/or drain contacts. The etching process may involve forming a mask to expose appropriate portions of the polysilicon.

Dielectric sidewall spacers are optionally formed about the polysilicon gate for mitigating high fields between the gate and the channel. For pJFET or nJFET devices, each sidewall spacer is generally approximately anywhere between 0-15 nm along the length of the device. The sidewall spacers may include two layers. More particularly, the sidewall spacers include a first layer of silicon dioxide immediately adjacent to the polysilicon followed by a layer of silicon nitride. In one embodiment, the sidewall spacers include a single layer sidewall material of, for example, silicon dioxide.

In process 410, the asymmetric channel link regions to be doped are defined. In an n-JFET, an n-link region in the channel is defined by a mask such that regions to be additionally doped can be exposed to dopants. In a p-JFET, a p-link region in the channel is defined by a mask such that regions to be additionally doped are exposed. In one embodiment, the mask opens the link regions on either side of the gate for dopant implantation. In asymmetric doping, the mask opening is also asymmetric about the drain side and source side of the gate. For example, the mask opens the source end link region and the portion of the drain side link region to be additionally doped.

The link region refers to a channel region between the drain and the gate and another channel region between the source and the gate. In general, for pJFET or nJFET devices, the link region is approximately 120 nm in length on each side of the gate although other dimensions may be implemented.

In one embodiment, the channel region between the source and the gate and approximately half of the channel adjacent to the drain between the drain side gate edge to the drain are exposed for additional doping (e.g., an abrupt doping profile). In general, in accordance with embodiments of the present invention, the drain-side link is more highly doped in a region closer to the drain than in a region closer to the gate.

In process 412, the defined regions of the channel link are implanted with additional impurities. N-type impurities are implanted for an n-JFET and p-type impurities are implanted for a p-JFET. In one embodiment, the exposed link regions are doped to a level that is approximately 10× or an order of magnitude grater than the doping density of the channel. In general, doping density of the exposed link regions may be anywhere between 2× to a doping density dependent on the solubility of the material in question. For example, the channel region may have a doping density of 1e¹⁸-1e¹⁹/cm³ and the doping density of the exposed link regions may be approximately 1e¹⁹-2e²⁰/cm³.

In process 414, the source and drain regions are formed. The source and drain regions may be formed according to any known and/or convenient manners, for example, by the diffusion of dopants through a corresponding polysilicon depositions. For an n-type JFET or a p-type JFET, the source/drain junction depth is generally approximately 70-75 nm although other implantation depths may be implemented.

In process 416, the gate region is formed. The gate region may also be formed according to any known and/or convenient manners, such as dopant diffusion through the polysilicon deposition defining the gate location. For an n-type JFET or p-type JFET, the gate junction depth is generally approximately 15-20 nm although other implantation depths may be implemented. The source/drain/gate length is generally 60 nm each however alternate dimensions may be implemented. In one embodiment, the source/drain/gate region doping density is approximately 1e²⁰-2e²⁰⁻/cm³.

From here, the remainder of JFET is formed using suitable fabrication techniques. For example, at least depositing a metallic material over one or more of the source region, the drain region, and gate region to form one or more ohmic contacts, and forming the metal interconnects.

The asymmetric JFET of embodiments of the techniques described herein, provides a number of enhancements in performance relative to conventional structures and devices, including but not limited to: lower sub-threshold slope (e.g., faster switching time), lower device off-current (e.g., less stand-by power dissipation), and improved low-voltage high-performance operation.

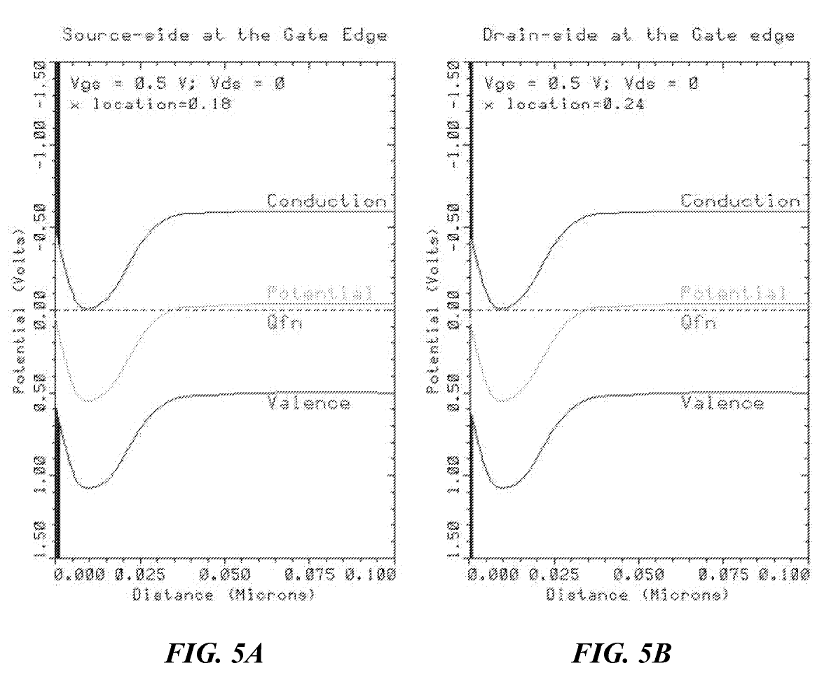

FIGS. 5A-B illustrates band diagrams of a symmetrically doped nJFET along the depth of the device at the source-side gate edge and the drain-side gate edge, respectively, when the gate-source (V_{gs}) is biased at 0.5V and no drain-source (V_{ds}) bias is applied, according to one embodiment.

The conduction band, valence band, and mid-gap levels are shown. For the nJFET, the electron quasi-fermi level (Q_{fn}) is shown along the depth of the device in dotted line. Under zero V_{ds}, the band diagram is symmetric about both sides of the gate. The channel can be approximately seen as the depth with band bending.

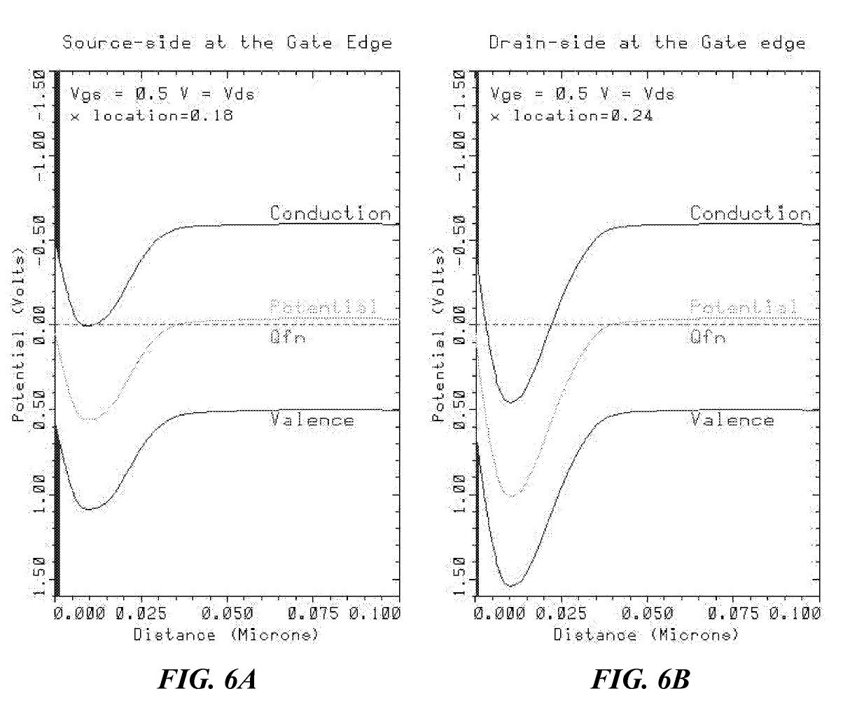

FIGS. 6A-B illustrates band diagrams of a symmetrically doped nJFET along the depth of the device at the source-side gate edge and the drain-side gate edge, respectively, when the gate-source is biased at 0.5V and the drain-source (V_{ds}) is biased, according to one embodiment.

Under applied V_{ds}, current is flowing between the source and drain terminals, as can be seen by the Q_{fn} level. However, the electron supply near the source edge in the symmetric device is limited as is apparent by the location of the quasi-fermi level relative to the conduction band edge in the channel region.

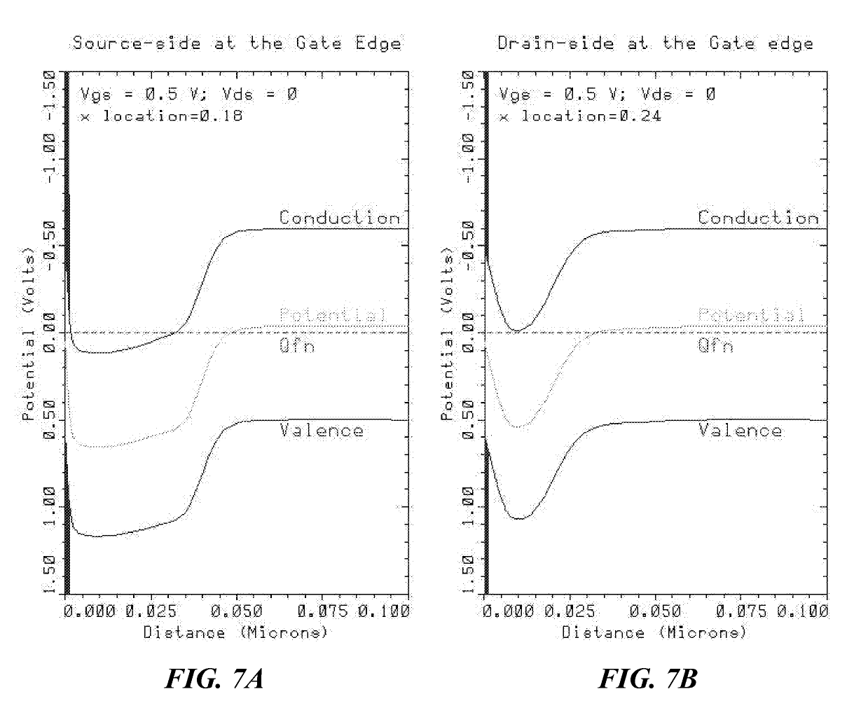

FIGS. 7A-B illustrates band diagrams of an asymmetrically doped nJFET along the depth of the device at the source-side gate edge and the drain-side gate edge, respectively, when the gate-source (V_{gs}) is biased at 0.5V and no drain-source (V_{ds}) bias is applied, according to one embodiment.

In the asymmetrically doped nJFET, the n-type dopant doping density is higher at the source side gate edge than at the drain-side gate edge thus providing additional carrier concentration near the source to improve on-current levels. The drain-side gate edge is lower doped to prevent high fields at the gate-channel junction thus reducing high field effects such as band-to-band tunneling at the junction.

The increased availability of carriers can be seem in the band diagram along the depth of the device at the source-side gate edge by the relative position of the quasi-fermi level relative to the conduction band compared to the same plot for the asymmetric device. The depth of crossing of the quasi-fermi level into the conduction band represents the amount of free carriers.

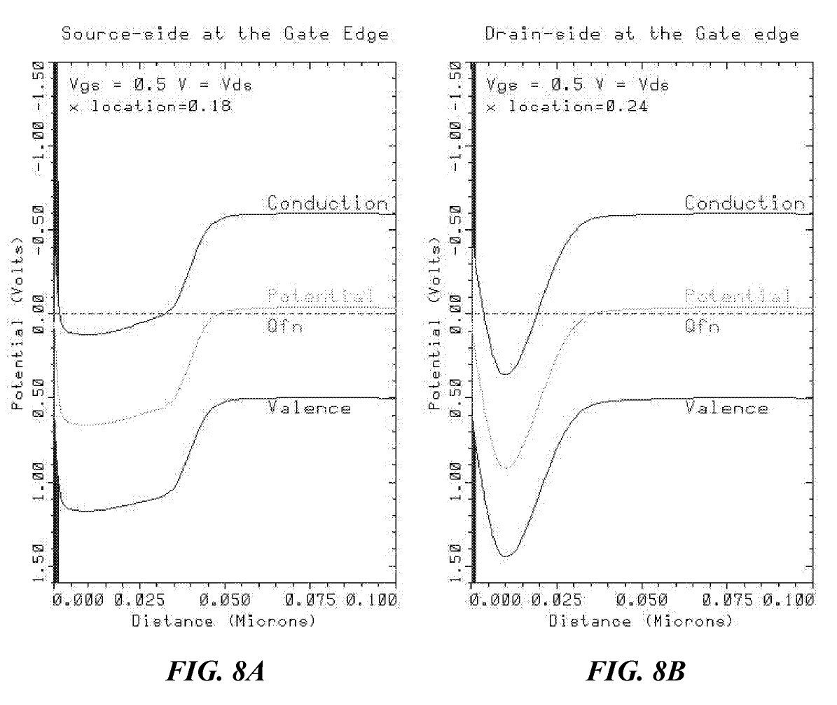

FIGS. 8A-B illustrates band diagrams of an asymmetrically doped nJFET along the depth of the device at the source-side gate edge and the drain-side gate edge, respectively, when the gate-source is biased at 0.5V and the drain-source (V_{ds}) is biased, according to one embodiment.

Under applied V_{ds}, current is flowing between the source and drain terminals, as can be seen by the Q_{fn} level, in particular, on the drain-side gate edge. The electron supply near the source edge in the asymmetric device is ample and greater than the electron supply near the source edge of the symmetric device which may not generally be ample or sufficient as is apparent by the location of the quasi-fermi level relative to the conduction band edge in the channel region.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” As used herein, the terms “connected,” “coupled,” or any variant thereof, means any connection or coupling, either direct or indirect, between two or more elements; the coupling of connection between the elements can be physical, logical, or a combination thereof. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or,” in reference to a list of two or more items, covers all of the following interpretations of the word: any of the items in the list, all of the items in the list, and any combination of the items in the list.

The above detailed description of embodiments of the invention is not intended to be exhaustive or to limit the teachings to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified to provide alternative or subcombinations. Each of these processes or blocks may be implemented in a variety of different ways. Also, while processes or blocks are at times shown as being performed in series, these processes or blocks may instead be performed in parallel, or may be performed at different times. Further any specific numbers noted herein are only examples: alternative implementations may employ differing values or ranges.

The teachings of the disclosure provided herein can be applied to other methods, devices, and/or systems, not necessarily to those described above. The elements and acts of the various embodiments described above can be combined to provide further embodiments.

These and other changes can be made to the invention in light of the above Detailed Description. While the above description describes certain embodiments of the invention, and describes the best mode contemplated, no matter how detailed the above appears in text, the teachings can be practiced in many ways. Details of the device may vary considerably in its implementation details, while still being encompassed by the subject matter disclosed herein. As noted above, particular terminology used when describing certain features or aspects of the invention should not be taken to imply that the terminology is being redefined herein to be restricted to any specific characteristics, features, or aspects of the invention with which that terminology is associated.

In general, the terms used in the following claims should not be construed to limit the invention to the specific embodiments disclosed in the specification, unless the above Detailed Description section explicitly defines such terms. Accordingly, the actual scope of the invention encompasses not only the disclosed embodiments, but also all equivalent ways of practicing or implementing the invention under the claims.

While certain aspects of the invention are presented below in certain claim forms, the inventors contemplate the various aspects of the invention in any number of claim forms. Accordingly, the inventors reserve the right to add additional claims after filing the application to pursue such additional claim forms for other aspects of the invention.

What is claimed is:

1. A semiconductor device, comprising:
a substrate of a first conductivity type;
a drain region and a source region each of a second conductivity type in the substrate;
a channel of the second conductivity type between the drain region and the source region in the substrate;
a gate region of the first conductivity type within the channel,the gate region being electrically operable to modulate a depletion width of the channel; and
the channel comprising (i) a first link region of the second conductivity type defined between the gate region and the drain region, and (ii) a second link region of the second conductivity type defined between the gate region and the source region;
wherein the first link region is more highly doped in a portion adjacent to the drain region than in another portion adjacent to the gate region.

2. The semiconductor device of claim 1, wherein the second link region of the second conductivity type is of substantially a constant doping density at a common depth along the length of the channel.

3. The semiconductor device of claim 1, wherein the first link region is more highly doped in a portion adjacent to the drain region than in a different portion adjacent to the gate.

4. The semiconductor device of claim 3, wherein a doping profile of the first link region has a graded transition in dopant density.

5. The semiconductor device of claim 4, wherein the graded transition in dopant density comprises a dopant transition from high dopant density to low dopant density and over a particular transition length.

6. The semiconductor device of claim 4, wherein the first link region comprises:
a lower density doped region extending along the channel from an edge of the gate region to a substantially midway position between the edge of gate region and an edge of the drain region; and
a higher density doped region extending along the channel from the substantially midway position, to the to the edge of the drain region;
wherein the edge of the gate region is proximal to the drain region and the edge of the drain region is proximal to the gate region.

7. The semiconductor device of claim 6, wherein, the second link region has a doping density that is substantially a same doping density as the higher density doped region of the first link region.

8. The semiconductor device of claim 7, wherein, a doping density of the higher doped region is greater than a doping density of the lower doped region by a factor of at least 2 times.

9. The semiconductor device of claim 1, wherein the drain region and the source region are electrically coupled to a first conductive layer and a second conductive layer, respectively; and
the first conductive layer corresponds to a drain electrode and the second conductive layer corresponds to a source electrode.

10. The semiconductor device of claim 9, wherein the gate region is electrically coupled to a third conductive layer corresponding to a gate electrode.

11. The semiconductor device of claim 10, wherein the first, second, and third conductive layers comprise one or more of a metallic material and a poly-silicon material.

12. The semiconductor device of claim 11, wherein the semiconductor device is a junction-field effect transistor (JFET).

13. The semiconductor device of claim 11, wherein the semiconductor device is a metal-semiconductor field effect transistor (MESFET).

14. The semiconductor device of claim 12, wherein the substrate comprises substantially silicon.

15. A method of fabricating a reduced leakage current field-effect transistor, the method comprising:
forming a channel region of a first conductivity type in a substrate;
depositing a polysilicon layer on the substrate including on the channel region;
patterning the polysilicon layer according to a predetermined location for one or more of, a source region, a drain region, and a gate region; and
further doping the channel region between the gate region, which is formed in the channel region, and the drain region with at least two doping levels of the first conductivity type;
wherein the source, drain and gate regions are formed in the substrate and spatially separated from each other.

16. The method of claim 15, wherein, the further doping comprises:
masking at least a portion of the gate region plus the portion of the channel region that extends from an edge of the gate region closest to the drain region to the intermediate position between the edge of the gate region and an edge of the drain region; and
diffusing impurities of the first conductivity type into the un-masked portion of the gate and the unmasked portion of the channel between the gate region and the drain region.

17. The method of claim 16, wherein the intermediate position comprises a substantially midway position between the edge of the gate region and an edge of the drain region.

18. The method of claim 15, further comprising, forming the source region, the drain region, and the gate region via diffusing impurities through the polysilicon layer.

19. The method of claim 18, further comprising: depositing a metallic material over one or more of the source region, the drain region, and gate region to form one or more Ohmic contacts.

20. The method of claim 15, wherein the doping of the channel region between the gate region and the drain region comprises a spatially asymmetric doping with a first portion of channel having a higher doping concentration than a second portion of the channel.

21. A method of differentially doping a field-effect transistor channel formed in a semiconductor substrate and having source, drain, and gate regions which are spatially separated, where the gate region is formed within the channel region, the method comprising:
masking at least a portion of the gate region plus the portion of the channel region that extends from an edge of the gate region closest to the drain region to the intermediate position between the edge of the gate region and an edge of the drain region; and
diffusing impurities into the un-masked portion of the gate and the unmasked portion of the channel between the gate region and the drain region so that the channel region between the gate region and the drain region is doped with at least two different doping levels along the length of the channel between the gate and the drain.

22. The method of claim 21, wherein the intermediate position comprises a substantially midway position between the edge of the gate region and an edge of the drain region.

23. The method of claim 21, wherein the doping of the channel region between the gate region and the drain region comprises a spatially asymmetric doping with a first portion of channel having a higher doping concentration than a second portion of the channel.

24. The method of claim 21, wherein the masking and diffusing of priorities are performed so that the at least two different doping levels provide for a changing doping level in the channel that is one of: (i) an abrupt transition in doping levels, and (ii) a graduated transition in doping levels.

25. The method of claim 21, wherein the method includes a plurality of masking steps with different masks and a plurality of diffusion of impurities steps to provide a desired plurality of different doping levels along the length of the channel between the gate and the drain.
